(19) United States
(12) Patent Application Publication
(10) Pub. No.: US 2026/0227187 A1
(43) Pub. Date: Aug. 6, 2026

(54) COAST AWARE PATH INTERPOLATOR

(71) Applicant: WISETECH GLOBAL (LICENSING) PTY LTD, Alexandria (AU)

(72) Inventors: Bogdan Vatulya, Alexandria (AU); James Balajan, Alexandria (AU)

(21) Appl. No.: 19/151,112

(22) PCT Filed: Jan. 31, 2023
(86) PCT No.: PCT/AU2023/050056

§ 371 Date: Jul. 25, 2025

(51) Int. Cl. G01C 21/20; G01C 21/00

(52) U.S. Cl. CPC G01C 21/203; G01C 21/3826; G01C 21/3867

(57) ABSTRACT

This disclosure relates to generating an output shoreline model such as for increasing the resolution of the model in certain areas. A computer receives historical vessel location data comprising for each of multiple vessels, multiple historical locations of that vessel and receives an input shoreline model defining waterways and landmasses. The computer then determines landmass areas in the input shoreline model that include the multiple historical locations of multiple vessels from the historical vessel location data and assigns the landmass areas in the input shoreline model that include the multiple historical locations to the waterways in the input shoreline model to thereby create an output shoreline model with an increased resolution at the waterway.

### CROSS-REFERENCE TO RELATED APPLICATIONS

The present application claims priority from Australian Provisional Patent Application No 2022900188 filed on 1 Feb. 2022, the contents of which are incorporated herein by reference in their entirety.

### TECHNICAL FIELD

This disclosure relates to interpolating a vessel path around geographical obstacles represented as polygons.

### BACKGROUND

Many thousand vessels, such as container ships or other cargo ships, travel waterways globally. For each of these vessels, it is important to have an accurate estimation of their travelled path. While positioning data is often available, there are some instances where positioning data is missing. In those instances, it is possible to interpolate the path between the existing positions. However, path interpolation that does not consider landmasses, such as islands, leads to paths that intersect with those landmasses. This is clearly inaccurate and undesirable. Furthermore, interpolation methods should be able to run on existing computer hardware, which means path interpolation should be computationally efficient so that interpolation can execute within short timeframes (e.g., minutes to hours).

There are models for landmasses, such as polygon shoreline models, which can be used to perform coast-aware path interpolation. However, there is difficult trade-off between computational complexity resulting from a high-resolution model versus inaccuracy resulting from a low-resolution model. In particular, it is difficult to consider paths along rivers because rivers, due to their narrow shape, only appear adequately in high-resolution models. In low-resolution models, the rivers are often not present or appear as one-dimensional lines, which is not adequate for accurate path interpolation. Using a higher resolution model would result in a prohibitive computational complexity-especially in cases where a large number of vessels are processed in real-time, which means processing has to complete between location updates.

### SUMMARY

A method for generating an output shoreline model comprises:
receiving historical vessel location data comprising for each of multiple vessels, multiple historical locations of that vessel;
receiving an input shoreline model defining waterways and landmasses;
determining landmass areas in the input shoreline model that include the multiple historical locations of multiple vessels from the historical vessel location data;
assigning the landmass areas in the input shoreline model that include the multiple historical locations to the waterways in the input shoreline model to thereby create an output shoreline model.

It is an advantage that the model assigns landmass areas to the waterways using the historical locations of a vessel. This way, the method essentially increases the resolution of the model in areas where the higher resolution is particularly desirable. Overall, this improves the accuracy of the model for vessel paths while not increasing the model size dramatically, which would occur if the entire model was changed to a higher resolution. The result is a model that is more accurate but still fits into available computer memory.

In some embodiments, the method further comprises:
providing a grid of cells over at least parts of the input shoreline model;
determining a density of the multiple historical locations in each cell of the grid; and
assigning the landmass to the waterway in response to the density being above a threshold.

In some embodiments, the method further comprises creating a polygon using the cells as points of the polygon to assign the landmass one side of the polygon to the waterway.

In some embodiments, creating a polygon comprises determining for each group of cells a shape of the polygon based on which cells of that group are above the threshold.

In some embodiments, the method further comprises performing a marching squares algorithm to assign the landmass areas to the waterways.

In some embodiments, the input shoreline model comprises one or more rivers represented as lines and the output shoreline model comprises the one or more rivers represented as polygon lines representing a waterway area.

In some embodiments, the input shoreline model and the output shoreline model are global models.

In some embodiments, the input shoreline model and the output shoreline model each comprise a visibility graph.

In some embodiments, the method further comprises interpolating a vessel path within the waterways in the output shoreline model.

In some embodiments, creating the output shoreline model comprises modifying the input shoreline model by subtracting areas including the multiple historical locations from the landmass areas in the input shoreline model.

In some embodiments, receiving the input shoreline model comprises reading a serialised file storing the input shoreline model.

In some embodiments, the input shoreline model comprises an adjacency matrix representing visibility between nodes of a visibility graph, and the adjacency matrix is serialised to the serialised file.

In some embodiments, the serialised file comprises fixed length fields.

In some embodiments, the method comprises using memory mapping to access the fixed length field.

In some embodiments, the method further comprises using a processor cache to cache fields of the serialised file that are geographically close on the processor cache.

In some embodiments, the method further comprises instantiating an array containing the fields that are geographically close to store the array in the processor cache and then iterating over the array.

In some embodiments, the method further comprises performing the steps of determining and assigning in multiple threads that each access a single copy of the input shoreline model from shared memory.

Software that, when executed by a computer, causes the computer to perform the above method.

A computer system comprises one or more processors configured to perform the above method.

A method for interpolating a vessel path around geographical obstacles represented as polygons comprises:
creating a visibility graph representing a visibility between points of the polygons;
storing the visibility graph for use by multiple executions of a pathfinding method;
receiving a source and a destination for execution of the pathfinding method from the source to the destination;
creating an updated visibility graph including the source and the destination by:
   determining a first edge in the visibility graph that is closest to the source along a direction between the source and the destination,
   connecting the source to the graph by connecting the source to the first edge,
   determining a second edge in the visibility graph that is closest to the destination along a direction between the source and the destination, and
   connecting the destination to the graph by connecting the destination to the second edge; and
executing the pathfinding method to find a path in the updated visibility graph from the source to the destination.

In some embodiments, the method further comprises creating a spatial index for edges that intersect a line between the source and the destination, the spatial index being indicative of a position of the intersecting edges along the line.

In some embodiments, executing the pathfinding method is performed conditional on the spatial index.

In some embodiments, the method further comprises performing the pathfinding in response to determining that at least one edge intersects the line; and returning the line as the path in response to determining that no edge intersects the line.

In some embodiments, determining the first edge comprises selecting the first edge that is closest to the source and intersects with a line between the source and the destination; and determining the second edge comprises selecting the second edge that is closest to the destination and intersects with the line between the source and the destination.

In some embodiments, the visibility graph comprises nodes associated with respective geographic locations stored with a fixed precision.

In some embodiments, the fixed precision is relative to degrees indicating a geographic location of each node. In some embodiments, the fixed precision is one micro degree. In some embodiments, the geographic location is stored as a 32 bit integer.

In some embodiments, storing the visibility graph comprises directly creating a mapping in an address space of a computer system by calling a low-level mapping function; serializing the visibility graph; and directly storing the serialised visibility graph in the address space.

In some embodiments, the method further comprises biasing the pathfinding method towards a greedier operation to increase computational speed.

In some embodiments, the pathfinding method comprises an A* method.

In some embodiments, the pathfinding method comprises Dijkstra's algorithm.

In some embodiments, the pathfinding method is based on a first set of vertices that are included in a shortest-path tree and a second set of vertices that are not yet included in the shortest-path tree and the pathfinding method comprises finding a vertex in the second set of vertices that has a minimum distance from a source.

In some embodiments, the method further comprises producing a user interface showing the path from the source to the destination.

Software, when executed by a computer, causes the computer to perform the above method.

A computer system for interpolating a vessel path around geographical obstacles represented as polygons comprises:
a data store configured to store the polygons representing the geographical obstacles;
a processor configured to perform the steps of:
   creating a visibility graph representing a visibility between points of the polygons;
   storing the visibility graph for use by multiple executions of a pathfinding method;
   receiving a source and a destination for execution of the pathfinding method from the source to the destination;
   creating an updated visibility graph including the source and the destination by:
      determining a first edge in the visibility graph that is closest to the source along a direction between the source and the destination,
      connecting the source to the graph by connecting the source to the first edge,
      determining a second edge in the visibility graph that is closest to the destination along a direction between the source and the destination, and
      connecting the destination to the graph by connecting the destination to the second edge; and
   executing the pathfinding method to find a path in the updated visibility graph from the source to the destination.

### BRIEF DESCRIPTION OF DRAWINGS

FIG. 1 illustrates the problem of vessel path interpolation.

FIG. 2 illustrates a visibility graph for the example scenario from FIG. 1.

FIG. 3 illustrates an updated visibility graph with connected source and destination.

FIG. 4 illustrates a determined path through the visibility graph from the source to the destination.

FIG. 5 illustrates a method for interpolating a vessel path around geographical obstacles.

FIG. 6 illustrates how to determine edges that are closest to the source and destination, respectively.

FIG. 7 illustrates the result of connecting the source and destination to their respective closest edges.

FIG. 8 illustrates a birds eye view of a typical shipping scenario showing a landmass on either side of a river.

FIG. 9 illustrates a method for generating an output shoreline.

FIG. 10 illustrates a grid of cells extending over an input shoreline model.

FIG. 11 illustrates the grid of FIG. 10 with binary values assigned to each cell.

FIG. 12 illustrates an example library of shapes.

### DESCRIPTION OF EMBODIMENTS

Vessel tracking is an important step in the process of shipping cargo around the globe. There are systems that provide current locations of vessels, such as the automatic identification system (AIS), which can provide global positioning system (GPS) coordinates for vessels. However, it is often the case that there are ‘gaps’ in the provided positions, such that an accurate position is not available for a period of time during the vessel's movement.

It is often desirable to produce a map in a user interface that shows the path the vessel takes. This may be a path of past positions of the vessel or a path of future predicted positions of the vessel. In any event, those paths are often incomplete due to the missing GPS data, for example. One option to generate a complete path is to interpolate between existing positions and within the gap where position data is missing.

However, most interpolation methods generate a straight line or curves that do not take into consideration whether a land mass is in the vessel's way. For example, if the vessel travels from A to B and a landmass is between A and B so that the vessel needs to travel around the landmass, existing interpolation methods would intersect with the landmass, which is clearly undesirable because the vessel cannot travel on land. So it would be desirable to have a more accurate method of interpolating vessel paths. Further, it would be desirable to have a method that is computationally efficient compared to existing methods.

### Path Interpolation

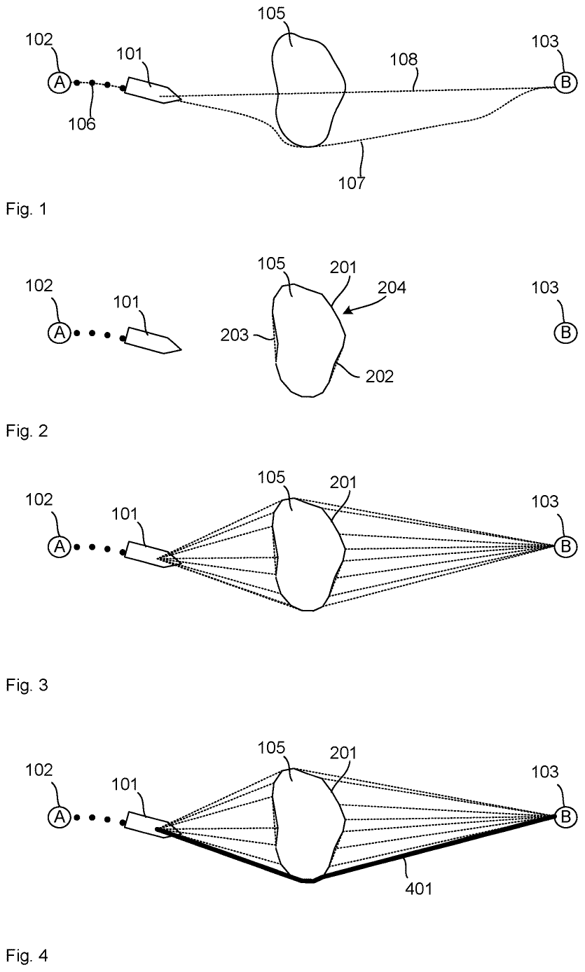

FIG. 1 illustrates the problem of vessel path interpolation, showing vessel 101 travelling from origin 102 to destination 103 around a landmass 105. Four past vessel positions, such as 106, are available but from the position shown at 101 no further positions are available. It is noted that typical vessel data does include the destination 103. The figure shows an actual path 107, which is not known at this stage. However, the destination 103 is known from the routing data available for vessel 101. In other examples, the vessel has already reached destination 103 and reported its GPS position from there, but no GPS positions are available along the actual travel path. One way of estimating the travel path is by linear interpolation, which generates an estimated path 108. It is clear that estimated path 108 is inaccurate because it leads across landmass 105.

### Visibility Graph

Another way of estimating the travel path is by building a graph representation of landmass 105 in FIG. 1 and performing a graph finding algorithm to find the shortest path through the graph. The graph that is particularly useful for this purpose is a visibility graph. In a visibility graph there are nodes that represent geographical locations and edges between the nodes indicate that the connected nodes can ‘see’ each other. That is, there is no obstructing landmass between nodes that are connected by an edge and a vessel can travel directly between two the connected nodes along the corresponding edge. In this sense, landmass 105 is approximated by a polygon 201 (shown in solid line in FIG. 2) and the corners of the polygon are nodes of a visibility graph 204. The edges of the polygon are also edges of the visibility graph 204 because two neighbouring points will always see each other.

There are two further edges in FIG. 2 indicated at 202 and 203 which indicate visibility of nodes past the immediately adjacent neighbour node and are also part of the visibility graph 204 but not part of the initial polygon 201 that approximates landmass 105. This occurs, for example, when the landmass polygon 201 is concave due to a bay or inlet. The visibility graph 204 shown in FIG. 2 can be generated once or obtained from third party sources for the entire world.

In one example, the visibility graph can be created by Lee's visibility graph algorithm described in Coleman, Dave. “Lee's O (n2 log n) Visibility Graph Algorithm Implementation and Analysis.” (2012) available from https://dav.ee/papers/Visibility_Graph_Algorithm.pdf. In essence, the algorithm described there computes the visibility graph Gᵥ from G(V, E) by computing the visibility graph of a single vertex n times. For each vertex vᵢ∈V, the visibility of all other vertices is calculated by 1) sorting all surrounding vertices in angular order from some starting scan line, 2) using a rotating plane sweep technique to visit each vertex in angular order and 3) keeping track of the distance of each surrounding line segment on the scan line in a sorted data structure. Once the visibility graph is created, it can be serialised and stored in a file on a file system. This file can remain unchanged until the topography changes or an update is desired for other reasons.

In some examples, the file is in a structured text format, such as in extensible Markup Language (XML) or JavaScript Object Notation (JSON). In other examples, the file is in a binary format. It has a header with a small amount of metadata, namely the number of polygons in the graph. Next, it serializes the actual polygons from the coastline map in a fixed point representation. Finally, the visibility graph itself is serialized as an adjacency matrix (but only half, since the matrix is symmetric). The adjacency matrix has a row for every node and a column for every node. So for n nodes the adjacency matrix is a n×n matrix and a cell is empty or has a bit value of ‘0’ if there is no visibility between two nodes and has an entry, such as a bit value ‘1’, if there is visibility between two nodes. The fixed point representation stores the coordinates as 32 bit integers (in micro degrees).

It is now assumed that vessel 101 only travels along edges of the visibility graph 204 which readily avoids the intersection with landmass 105. It is an aim to find the shortest path along those edges. However, the position of vessel 101 is typically different every time this method is performed, which means vessel 101 is connected to the visibility graph 204 every time the method is performed.

One way of connecting vessel 101 to the visibility graph 204 is to perform a visibility analysis to determine nodes that are visible by vessel 101. It is noted that vessel 101 is also referred to as the ‘source’ because it is the source of the path finding algorithm. Accordingly, the ‘source’ may also be the last reported location before the gap and the destination is the first reported location after the gap.

FIG. 3 shows the result of connecting vessel 101 to the visibility graph 204 which results in an additional edge between vessel 101 and each of the nodes that are visible from vessel 101. The figure also shows edges that indicate nodes that are visible from the destination. The graph shown in FIG. 3 can be used to determine the shortest path from the source (vessel 101) to the destination 103 avoiding landmass 105. The shortest path 401 for this example is shown in thick line in FIG. 4.

While the above method works well for small problems where the number of nodes of the polygon 201 is small, it has been found that for large problems, and in particular where the entire world is represented in one graph, the computational complexity becomes problematic. One particular problem that has been identified is the step of adding vessel 101 and destination 103 to the graph as shown in FIG. 3, because this step has to be performed again when the vessel 101 has moved.

### Improved Graph Generation

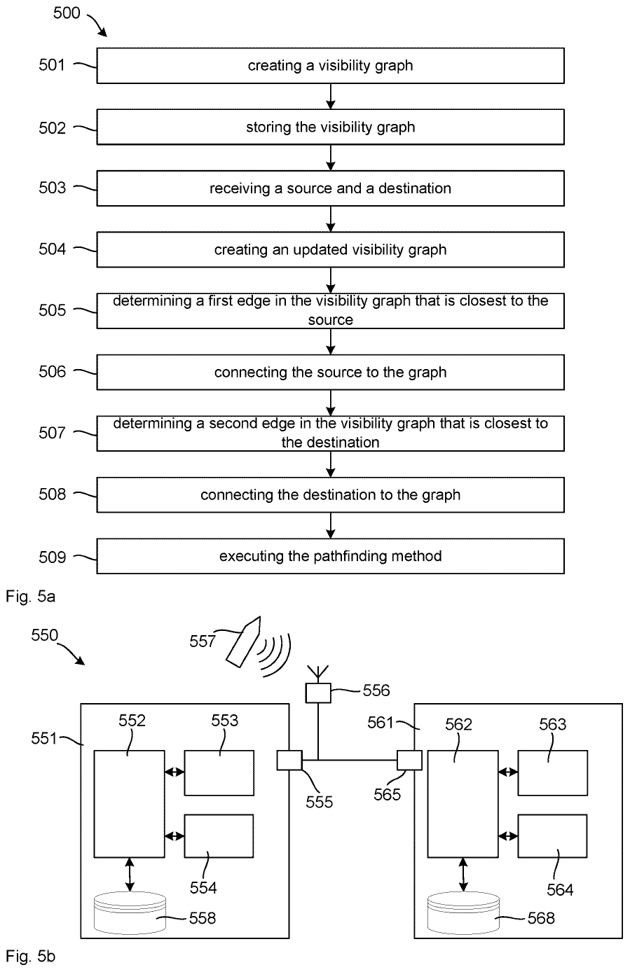

In order to address this problem, FIG. 5a illustrates a method 500 for interpolating a vessel path around geographical obstacles represented as polygons, such as polygon 201 in FIGS. 2-4. The method is performed by a processor of a computer system, which executes instructions represented in a software program to execute method 500.

### Computer Implementation

FIG. 5b illustrates a computer network 550 comprising a first computer system 551 and a second computer system 561. First computer system 551 comprises a processor 552, non-transitory program memory 553 and data memory 554, which may be transitory, such as random access memory (RAM) or non-transitory, such as a hard disk drive. Processor 552 executes program code stored on program memory 553, which causes processor 552 to perform method 500. The program code stored on memory 553 may also be referred to as a first software system. More particularly, the methods disclosed herein are implemented in a program language and then compiled into binary form and installed on program memory 553, for example.

First computer system 551 further comprises a communication port to receive location data from a location data receiver 556, which, in turn, receives the location data from a vessel 557 over wireless communication. As described above, vessel 557 may carry a GPS sensor and send the GPS coordinates wirelessly to receiver 556. Other sensors may equally be used, such as Global Navigation Satellite System (GLONASS), BeiDou or Galileo. The location determined by satellite navigation using these systems may be improved by assistance technology, such as assisted GPS. Other non-satellite based location system, such as inertial navigation systems or dead reckoning may equally be used for location determination.

In further examples, the geographic location data comprises data from the automatic identification system (AIS), which may be transmitted from each vessel to a terrestrial receiver (T-AIS) or to a satellite (S-AIS). The data from the various different receivers may be aggregated and provided over the Internet. In that way, processor 552 can receive the location data over the Internet, such as by calling API calls of a AIS data provider, such as Marine Traffic.com, Vesselfinder.com, or Spire Marine.

Processor 552 receives the geographic location data generated by receiver 556 through communication port 555, which maybe a wide area network (WAN) or local area network (LAN) interface. In other examples, processor 552 receives the location data from database 558 where historical location data is stored, such as recorded locations of all available vessels for the last year, for example.

As described in more detail herein, processor 552 performs graph operations and executes a pathfinding method to determine a path that avoids landmasses.

Processor 552 may also produce a map in a user interface that shows the interpolated path the vessel takes. That is, the user interface shows the edges of the visibility graph that make up the determined path. This may be a path of past positions of the vessel or a path of future predicted positions of the vessel. The user interface may also show the landmasses, such that the path is an overlay over the map of a particular geographical area. It is noted that the path estimation is now more accurate, which means the user interface shows more accurate data to the user in the sense that the interpolated path does not intersect with any of the landmasses.

### Tracking Data Output

Once processor 502 has determined the path, processor 502 may also determine or receive tracking data, such as by detecting the departure of a vessel. Processor 502 may then generate an event to notify second computer system 561 of the detected departure. Second computer system also comprises a second processor 562, second program memory 563, second data memory 564 and a second database 568. Program code that is installed on second program memory 563 may also be referred to as the second software system. Second processor 562 may provide an API that processor 552 can call, such as by calling a web-API function at SecondComputerSystem.com/api/vesselDeparted?vesselID=123. The web location SecondComputerSystem.com may be replaced by an internet protocol (IP) address. As can be seen in this example, the API function call includes a vessel identifier vesselID, which is 123 in this case. The API function call is an event generated by processor 552 upon determining that a vessel has departed the port.

It is also possible that first computer system 552 exposes an API and second processor 562 calls an update request function. Upon determining that the vessel has departed, processor 552 generates the event in the form of a response to the update request. That is, the generated event may be a change in value of a return variable.

In response to receiving the tracking data, such as through the API, the second computer system 561 may perform an action, which is then said to be triggered by the event generated by the processor 552 of the first computer system 551.

While FIG. 5 illustrates an example computer network with two distinct hardware systems, it is noted that the described methods may equally be performed on the same hardware system, such that two software systems communicate with each other. In that sense, the first software system generates an event that triggers an action by the second software system. For example, the first and second computer systems 551 may be implemented on a cloud computing environment on a dynamically changing number of computing and storage instances. The API calls provided below may also be replaced by function calls, or inter-process communication or by storing files with tracking data on non-transitory data memory 554.

### Method

Returning to FIG. 5a, processor 552 first creates 501 the visibility graph 204 representing a visibility between points of the polygons as illustrated in FIG. 2. As explained above, the edges of the visibility graph 204 indicate that the connected nodes are visible to each other. In terms of vessel movement, an edge means that a vessel can travel directly between the two connected nodes. If two nodes are not connected, this means that there is an obstacle between those nodes (such as a landmass) and the vessel cannot travel directly between those nodes.

The processor stores 502 the visibility graph 204 for use by multiple executions of a pathfinding method. As discussed above, the visibility graph 204 including polygon 201 that approximates the landmass 105 and the additional edges 202 and 203, remains static and are generated only once. This can be performed for the entire world so as to generate polygons and other edges of the visibility graph for all landmasses of the world.

The processor then receives 503 a source and a destination for execution of the pathfinding method from the source to the destination. For example, the processor 503 may also perform a vessel tracking method which receives and tracks GPS coordinates of the vessel. The processor may then estimate/interpolate the vessel movement from the current or last location (the “source”) to the destination by performing the path finding method disclosed herein.

In order to adapt the existing, static visibility graph 204 to the current, dynamic situation, that is, location of source 101, the processor creates 504 an updated visibility graph including the source and the destination.

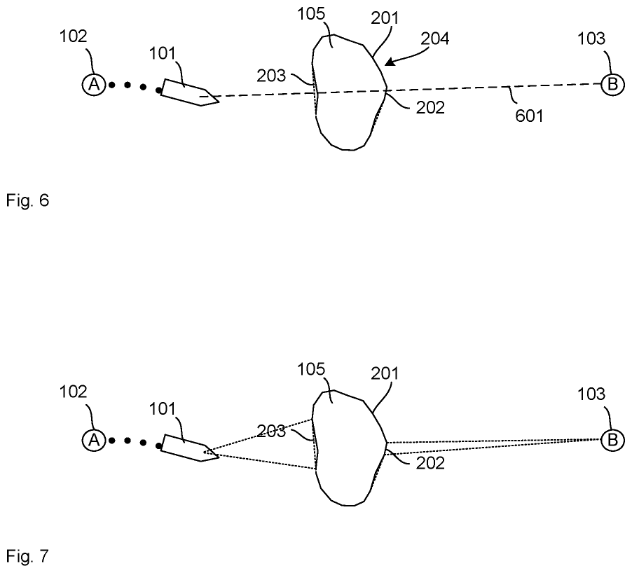

In contrast to FIG. 3, the processor determines 505 a first edge in the visibility graph that is closest to the source along a direction between the source and the destination. FIG. 6 illustrates this concept showing the source 101, the visibility graph 204 and a dashed line 601 that represents the direction between the source 101 and the destination 103. As can be seen, dashed line 601 intersects the visibility graph 204 and therefore intersects edges of the visibility graph 204. More particularly, dashed line 601 intersects first edge 202 and second edge 203. As it turns out in this example, the closest edge to the source 101 along the direction between the source 2041 and the destination 103 is edge 203.

The processor now determines the closest of these edges by determining the distance along dashed line 601 between the source 101 and the intersection point. More specifically, the processor creates a spatial index for edges that intersect line 601. The spatial index is indicative of the position of the intersecting edges along the line. For example, the processor may maintain a counter that starts with the first edge 202 and is incremented for each edge that intersects the line. In the small example of FIG. 6, edge 202 would have a counter value of ‘0’ and edge 203 a counter value of ‘1’ as respective spatial index values. This spatial index is much less complex to determine compared to calculating the actual geographical distance between points.

The processor then connects the source 101 to the edge with the largest spatial index value and destination 103 to the edge with the smallest spatial index value. If no edge intersects with line 601 the processor determines that line 601 is an estimate for the path of vessel 101. That is, the processor only performs the path finding method if there is at least one edge that intersects with line 601.

Accordingly, the processor connects 506 the source 101 to the visibility graph 204 by connecting the source to edge 203. The processor connects the source 2041 by creating one or more new edges between the source 2041 and nodes of the visibility graph 204. More particular, the processor creates one or more edges between the source 101 and nodes of the edge 203 that is closest to the source 101. In some examples, the processor adds two edges comprising one edge to each node of edge 203 as shown in FIG. 5. In other examples, the processor selects the node of edge 203 that is closest to the source 101 and only creates one edge to that node.

Similarly, the processor determines 507 another edge 202 in the visibility graph 204 that is closest to the destination 103 along a direction between the source 101 and the destination 103 and connects 508 the destination 103 to the visibility graph 204 by connecting the destination 103 to the determined edge 202. Again, the connection may be by way of two added edges to both nodes of edge 202 or only a single edge to the closest of the two nodes.

Once the updated visibility graph 204 as shown in FIG. 7 is at hand, the processor executes 509 the pathfinding method to find a path in the updated visibility graph from the source 101 to the destination 103.

### Path Finding

There may be a range of different pathfinding algorithms that can be used to find a path from source 101 to destination 103 along the edges of the updated visibility graph. One example is the A* search algorithm published in Hart, P. E.; Nilsson, N. J.; Raphael, B. (1968). “A Formal Basis for the Heuristic Determination of Minimum Cost Paths”. IEEE Transactions on Systems Science and Cybernetics. 4 (2): 100-7, which is incorporated herein by reference. The A* algorithm is an informed search algorithm, or a best-first search, meaning that it is formulated in terms of weighted graphs: starting from a specific starting node of a graph, i.e. source 101, it aims to find a path to the destination node having the smallest cost (least distance travelled, shortest time, etc.). It does this by maintaining a tree of paths originating at the start node and extending those paths one edge at a time until its termination criterion is satisfied.

At each iteration of its main loop, A* determines which of its paths to extend. It does so based on the cost of the path and an estimate of the cost required to extend the path all the way to the goal. Specifically, A* selects the path that minimizes

f(n)=g(n)+h(n)

where n is the next node on the path, g(n) is the cost of the path from the start node to n, and h(n) is a heuristic function that estimates the cost of the cheapest path from n to the destination. A* terminates when the path it chooses to extend is a path from start to goal or if there are no paths eligible to be extended. The heuristic function h(n) is problem-specific and may be the geographical distance between n and the destination.

It is possible to use an existing library to perform the above steps, such as the pyvisgraph library available under GitHub by Christian Reksten-Monsen (TaipanRex).

Since the A* algorithm is an extension of Dijkstra's algorithm, it may also be possible in some applications that the processor performs Dijkstra's algorithm, although efficiency may become an issue for large problems. More specifically, the processor maintains two sets, one set contains vertices included in the shortest-path tree, other set includes vertices not yet included in the shortest-path tree. At every step of the algorithm, the processor finds a vertex that is in the other set (set of not yet included) and has a minimum distance from the source. In yet another example, the processor performs Lee's path finding algorithm (Lee, C. Y. (1961), “An Algorithm for Path Connections and Its Applications”, IRE Transactions on Electronic Computers, EC-10 (2): 346-365), which is a breadth first search. It follows a wave expansion paradigm where all neighbours of the origin are labelled with a distance (‘1’) from the origin and in the next step all neighbours of the neighbours are labelled with distance ‘2’ and so on. The algorithm then backtraces from the destination by selecting a next node in the path that has a lower distance than the current node.

### Acceleration

In order to accelerate computation of the method disclosed herein, the processor may store the geographic locations of the vessel as well as the nodes of the visibility graph 204 in a fixed precision variable in a computer program. This is in contrast to a floating point variable. The fixed precision variable may be an integer, such as a 32 bit integer. Such an integer can store each geographical location at a precision of one micro degree ( 1/1,000,000 degree) in relation to longitude and latitude. Due to the more efficient processing of integers compared to floating point variables, the use of fixed precision variables significantly increase the computational speed of the method. Further, floating point errors are avoided, which increases accuracy. More particularly, equality is not well defined for floating point numbers. On the other hand, it is unambiguous whether two integers or fixed precision numbers are equal. For floating point numbers, in some cases the poorly defined inequality leads to a false positive in the sense that the processor determines that a node is visible although it is actually not. In that case, the visibility graph would contain self-intersecting edges which can lead to incorrect results. The processor eliminates these inaccuracies by using fixed precision numbers or integer numbers.

A further way of increasing performance of the methods disclosed here in is in the way to store the visibility graph 204 by using low-level functions instead of typical operating system functions for storing data objects. More particularly, the processor may directly create a mapping in an address space of the computer system by calling a low-level mapping function. This reserves space on persistent computer memory, such as a hard disk or solid state disk. The processor can then serialize the visibility graph 204 and directly store the serialised visibility graph in the mapped address space on the persistent memory.

In yet a further way to increase performance, the pathfinding method can be adjusted towards a greedier operation. This means that the processor chooses nodes with lower heuristic cost more readily. In other words, the optimisation favours the heuristic part of the A* algorithm more than the exact distance from the source to the node n. For example, the A* equation is changed from

$$f ( n ) = g ( n ) + h ( n )$$

to

$$f ( n ) = ( 2 - w ) * g ( n ) + w * h ( n ) ,$$

where w is an adjustable parameter for the “greediness”>1. This may increase the risk of not finding the best possible path through the visibility graph 204. However, for some applications, it is less significant that the path is optimal as long as landmass obstacles are avoided. On the other hand, this greedier approach means that the processor visits fewer paths and therefore, the processing time is reduced significantly.

The optimisations disclosed herein are particularly useful where the data (e.g., vessel positions) comes into the system at a certain rate, such as a number of locations per unit of time. If the disclosed system processes this volume at a slower rate, the problem becomes infeasible, but with the optimisations disclosed herein, it is possible to process the locations of vessels faster than they are generated, which may also be referred to as real-time processing.

### Results

The performance characteristics of the disclosed methods were tested through a series of benchmarks. On local machines when benchmarking the methods against PyVisGraph and on the AWS EC2 instances when benchmarking visibility graph generation on the high-resolution maps. The former was to ensure that the hypothesis of the disclosed methods being more performant than the pre-existing solution is valid. The latter was to ensure that the performance is sufficient for particular applications.

The results:
Graph generation using the disclosed method is 3.7 times faster than PyVisGraph on low resolution graphs (5065 vertices).
High resolution graph generation takes approximately 10 hours on M.2 AWS EC2 instance with 96 cores and 128 GB of memory.
Interpolation using the disclosed method is 9.5 times faster than PyVisGraph on coarse graphs (656 vertices).
Interpolation using the disclosed method is 9 times faster than PyVisGraph on low resolution graphs (5065 vertices).
Interpolation for the whole history of events of a history-rich vessel is within the acceptable range provided certain reasonable expectations are met by the disclosed method.

This disclosure provides a solution to path interpolation between missing GPS positions that is accurate and computationally feasible for a large number of vertices.

### Data-Driven Map Generation

As set out before, there exists a problem with shoreline models that high resolution models result in excessive computational complexity for path finding while low resolution models do not represent fine waterways, such as rivers accurately in two dimensions. Resolution in this context may be defined as a maximum distance between two points defining a polygon that represents a shoreline. A shoreline in general is a delineation between landmass areas and waterways in the model. However, the shoreline model also includes single lines to represent rivers which therefore do not delineate between waterways and landmasses but only give a rough indication on the location of the river, but not its width, which is typically variable along the river.

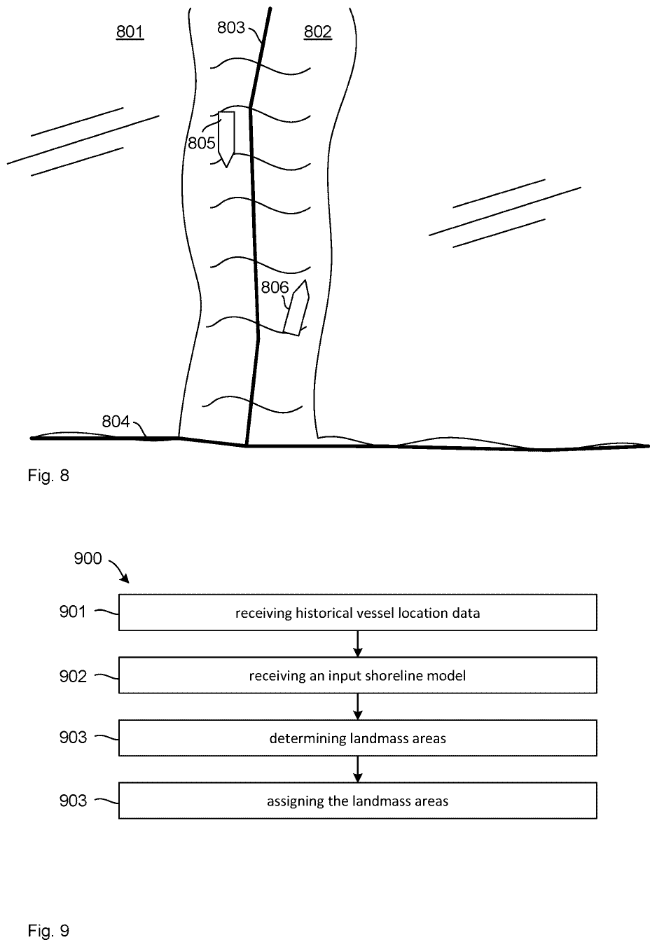

FIG. 8 illustrates a birds eye view of a typical shipping scenario showing a landmass 801 on either side of a river 802. A shoreline model represents the river as a single line 803 that is connected to a further line 804 that represents the shore of a larger body of water, such as an ocean. Vessels 805 and 806 travel along river 802 but as can be seen visually, vessels 805/806 do not travel along line 803. Therefore, it is difficult to accurately predict vessel movement or interpolate vessel movement between two points.

FIG. 9 illustrates a method 900 for generating an output shoreline model that is more accurate for rivers and other fine waterways than existing coarse models without increasing computational complexity excessively. In particular, the method only adds details to bodies of water that are actually navigated by vessels that provide location information.

The method 900 commences by receiving 901 historical vessel location data. This data comprises for each of multiple vessels, multiple historical locations of that vessel. For example, the data may comprise AIS data including multiple GPS positions along the path of each vessel. The link between the locations and the actual path is not necessary, which means that link can be discarded. In other words, method 900 operates on the multiple locations without reference to the time stamp of these locations. This means there may be no temporal component to the data analysis of method 900 and the historical locations are an unordered set of locations without any relationship between them. It is noted, however, that there may be a relationship that is maintained but this is not necessary for the functioning of the method disclosed herein.

Next, method 900 comprises receiving 902 an input shoreline model defining waterways and landmasses. For example, this input shoreline model may be obtained from the Global Self-consistent, hierarchical, high-resolution Geography Database (GSHHG) https://www.soest.hawaii.edu/pwessel/gshhg/in a resolution that shows rivers as lines. The model shows lakes and oceans as polygon shapes or areas. Viewed in another way, it can also be said that the model shows landmasses and the waterways are defined by a lack of landmass or simply by being outside the polygons defined as landmass. This again shows the problem that there is a polygon to define a landmass and within the polygon there is a single line that defines a river. However, that river has no width as it is only a line and not technically part of a closed polygon or area.

The method 900 then determines 903 landmass areas in the input shoreline model that include the multiple historical locations of multiple vessels from the historical vessel location data. In other words, method 900 determines which landmass areas actually have vessel locations in them, which means they are actually not landmass areas but waterways. More specifically, these areas have been defined as landmass in the model as a result of oversimplification by defining rivers as lines without width, but in reality, those areas are waterways.

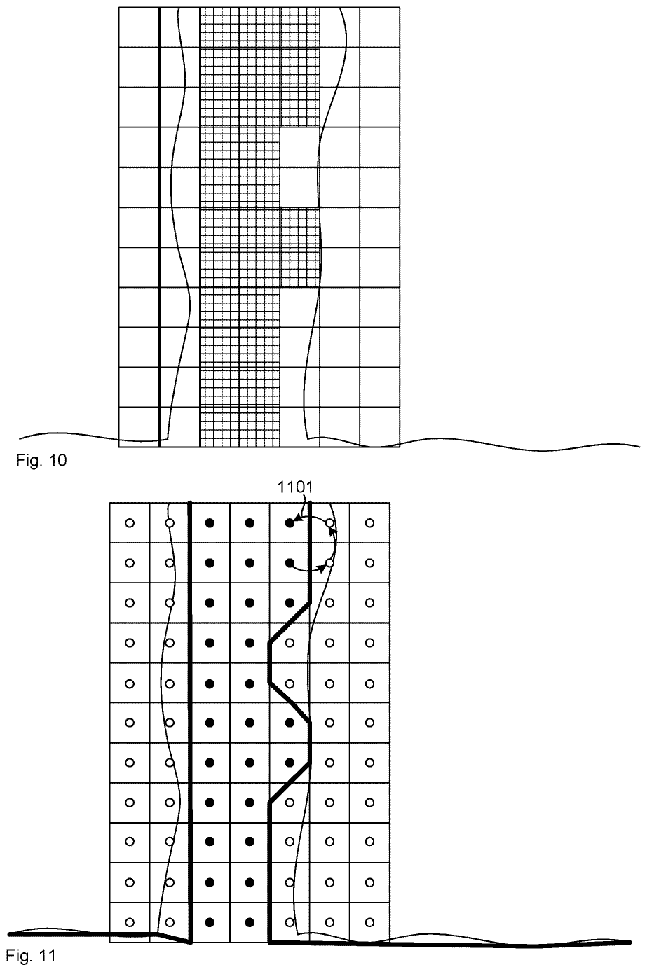

To that end, method 900 provides a grid of cells as shown in FIG. 10. The grid of cells extends over at least parts of the input shoreline model. For example, the grid of cells may extend over all parts that have at least one vessel location. In other embodiments, the grid of cells extends for a predefined distances from the line in the shoreline model that defines the border between water and landmass. The model may specifically denote lines as rivers and then the method 900 can extend perpendicular to those lines by the predefined distance.

This predefined distance may be set by the maximum distance of a river or other waterway that may be represented as a line in the shoreline model. This distance may be 100 m or 500 m. It can be seen in FIG. 10 that the grid cells extend either way from the line representing the river. The size of the grid cells may be chosen based on a desired accuracy and may range from 1 m to 100 m, or may be 10 m or any other suitable size.

Method 900 then calculates a density of the historical locations in each cell of the grid. For example, method 900 counts the number of historical locations that are located with each grid cell, respectively. There may be a threshold defined to filter noise or incorrect historical locations from the dataset. That threshold could be zero for no filtering or could be 10 or 100 locations. The threshold could also be calculated based on the overall number of locations or an average size of locations. In FIG. 10 the cells with locations above the threshold are shaded.

Method 900 may then assign a binary value to each grid cell. The binary value indicates whether the number of locations within the grid cell is below or equal (value ‘0’) or above (value ‘1’) the threshold. FIG. 11 shows the grid with each binary value indicated as a dot in the centre of the respective grid cell. A black dot indicates that the number of locations in that grid is above the threshold.

Method 900 then assigns the landmass areas in the input shoreline model that include the multiple historical locations to the waterways in the input shoreline model. In other words, landmass areas that have previously been part of the landmass because the shoreline model defined the river as a one-dimensional line, can now be assigned to be waterways instead. This means that these areas are effectively subtracted from the shoreline model in the sense that these areas are subtracted from the landmass. In yet another way, method 900 adds polygon points to the shoreline model to exclude, subtract or “cut out” certain areas which are then waterways because they are now outside the landmass polygons. If the landmass is positively defined by the shoreline model, then subtracting the areas from the landmass effectively assigs these areas to the waterway. Thereby, the method creates an output shoreline model that is now more accurate since it more accurately represents the river as a two-dimensional waterway instead of a one dimensional line.

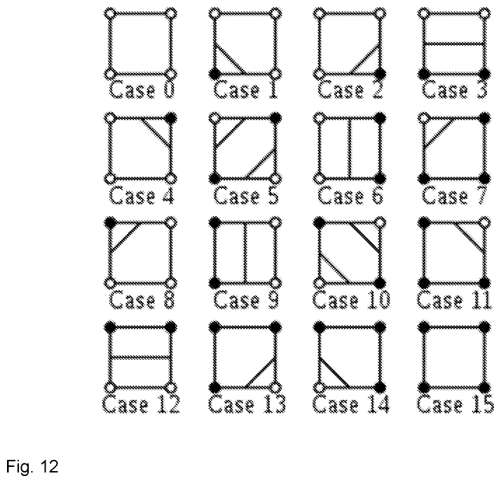

More specifically, the method assigns the landmass to the waterway in response to the density being above a threshold. In FIG. 11, the cell centres that have locations above the threshold are assigned to the waterway. More specifically, method 900 may perform a walking squares algorithm. This means that the method considers each 2×2 square of centre points. Each centre point is assigned a ‘0’ or ‘1’ value as set out above. The method starts at the top left centre point of the 2×2 square and proceeds clockwise over the four centre points. This way, the method appends the value assigned to the current centre point to an overall number. FIG. 11 shows an example 2×2 square with a corresponding path 1101 over the four centre points of that square. In this example, the values form the number ‘1001’ (=9) because the first and last centre points of the path are above the threshold while the middle two points are below the threshold. The method then access a library of 16 shapes that are indexed by respective numbers indicating the number for the path through the centre points. FIG. 12 illustrates an example library of shapes and the method chooses Case 9 corresponding from the number obtained along the path over the four centre points. It can be seen in FIG. 12 that Case 9 is a vertical line. Therefore, method 900 chooses the vertical line as shown in bold in FIG. 11 for path 1101. Method 900 then moves on to the next 2×2 square of centre points and repeats the steps of obtaining the binary number to then select one of the 16 shapes. Finally, method 900 adds the selected shapes, as polygon lines, to the shoreline model to subtract the waterway from the landmass.

The result is shown in FIG. 11 in bold line. It can be seen that the bold line now defines the river as a two-dimensional object, which allows accurate tracking, interpolation and prediction. In this sense, method 900 creates a polygon using the cells as points of the polygon to assign the landmass one side of the polygon to the waterway and for each group (i.e. square) of cells, the method chooses a shape of the polygon based on which cells of that group are above the threshold. As a result, output shoreline model comprises the river represented as polygon lines representing a waterway area.

It is interesting to observe that the proposed method also adds islands and other landmass areas within the river to the shoreline model. This is so because islands would not have any recorded historical vessel locations. Therefore, the points on the islands would be below the threshold. As a result, method 900 chooses shapes on the edges of the island, i.e. on the edges to waterway areas that have recorded historical vessel locations, that define the shape of that island. By adding the selected shapes to the shore model, method 900 essentially adds the island to the model. Using the interpolation method disclosed herein, a vessel path can be interpolated to track around the island rather than intersecting across the island. This leads to a more accurate display of interpolated vessel paths, a more accurate display of a predicted vessel path and a more accurate prediction of vessel movement, such as estimated time of arrival.

It is noted that method 900 is particularly advantageous with large input and output shoreline model because such models would increase in size significantly if the resolution is increased across the entire model to represent rivers accurately. This is because an increase in resolution would not only widen rivers, but would also increase the number of polygon points almost everywhere in the model, such as along coastlines of oceans where a higher resolution is not required. For example, the method is particularly advantageous if the input shoreline model and the output shoreline model are global models where the increase in resolution is impractical. For example, an increase in resolution can easily lead to a 100-fold increase in model size. So instead, only the rivers that are navigable and therefore have historical locations, are represented by the output model in addition to the relatively low resolution shoreline model. Global in this context means that the model describes shorelines everywhere on the Earth or at least a substantial part of the shorelines on the Earth, such as the main continents or all areas on the Earth that are relevant for vessels tracking. For example, global models that exclude Antarctica are still global models in the sense that routes from one side of the globe to another side of the globe, or between any two ports on the Earth, fall within the same model. In yet another way, there is only a single model for all vessel routes that are being considered.

Since transport vessels often travel across substantial parts of the globe, it is desirable to maintain a global model to accurately determine the globally optimal path that the vessel is predicted to take. Therefore, the above described problem of large model size is particularly relevant for vessel tracking. In other words, the higher resolution of the map, the more nodes are on the graph and the more memory is needed to store it. The lower resolution of the map—the less accurate the shoreline is represented and the less accurate is the result of the path finding is.

The present disclosure provides a solution that first relies on a relatively low resolution map but over time, the disclosed method uses historical locations of vessels to improve the resolution of the map locally by assigning landmass areas to waterways at locations where vessel locations have been recorded. This way, the map becomes high resolution in areas where high resolution is desired, such as along rivers, while the size of the entire model does not increase dramatically and still fits into computer memory available in current computer systems. This avoids the need for splitting the global model into local sub-models, which would lead to sub-optimal path estimation and has a large number of technical difficulties. It is noted that some examples disclosed herein relate to rivers, but the method is equally useful to increase the resolution of the model in other areas than rivers, such as in coastal areas where the shape of the cost is very complex and therefore oversimplified, or overly smoothed due to the initial low resolution of the model.

Once the shoreline model is updated to represent rivers properly, method 900 may interpolate a vessel path within the waterways in the output shoreline model as described herein. Again, since the output shoreline model is a global model, the entire vessel path is in the same model, which means that the path is globally optimal.

### Implementation Details

In some examples, the input shoreline model (and potentially the output shoreline model) is available as a single file or split across multiple files. Those files are stored on a typical file system on computer storage, such as a hard drive or solid state disk, and contain a list of polygons with corresponding points. The polygons and corresponding points are stored as a sequence of records. Therefore, the file objects are also referred as a serialised files. This typically includes text files and binary files. In one example, the shoreline models are stored in a shapefile format defined by Environmental Systems Research Institute (ESRI).

The shapefile format stores the geometry as primitive geometric shapes like points, lines, and polygons. These shapes, together with data attributes that are linked to each shape, create the representation of the geographic data. Although the term “shapefile” is used, the format may consist of a collection of files with a common filename prefix, stored in the same directory. The three mandatory files have filename extensions .shp, .shx, and .dbf. The actual shapefile relates specifically to the .shp file, but alone is incomplete for distribution as the other supporting files are required.

### Mandatory Files Include:

.shp—shape format; the feature geometry itself {content-type: x-gis/x-shapefile}
.shx—shape index format; a positional index of the feature geometry to allow seeking forwards and backwards quickly {content-type: x-gis/x-shapefile}
.dbf—attribute format; columnar attributes for each shape, in dBase IV format {content-type: application/octet-stream OR text/plain}

The shapefile may comprise fixed length fields. For example, the shapefile may comprise a header of 100 bytes and then any number of records. The records can have different length but the length of each record is stored in the record header of 8 bytes. There may also be an index file that contains a positional index of the feature geometry. Using this index, it is possible to seek backwards in the shapefile. In particular, a backwards search is possible in the search file because the index file has fixed-length records. The processor can then read the record offset to then seek in the correct position in the .shp file.

The input shoreline model may be a visibility graph that indicates which nodes of the shoreline are visible from other nodes of the shoreline. The visibility graph may be created by the processor performing Lee's visibility graph algorithm as explained above. When method 900 receives the input shoreline model, this means a computer processor reads a serialised file storing the visibility graph into memory. It is noted, however, that it is not necessary to read the entire file but instead, individual chunks may be read. To that end, the processor uses memory mapping to access the fixed length fields. For example, the processor may execute program code that uses the mmap function that is available in many programming languages. The mmap function enables the reading of specific memory areas which is useful to read the desired records of the visibility graph. Again, this facilitates the use of mmap. As a result, accessing the desired visibility information is significantly faster because it is not necessary to read the entire file. Further, the memory usage is significantly reduced, again, because most of the visibility graph can remain on permanent memory (HD or SSD etc.).

In a further aspect, the processor comprises a processor cache, which is memory integrated into the processor chip package. As a result, the processor cache is significantly faster to read and write than external random access memory (RAM). It is now possible to read the fields of the serialised file into the cache (cache the serialised file) that are geographically close or visible and therefore more likely to be required in the model update. The processor may comprise different level of caches, such as level 1 and level 2 caches. It is often not possible to explicitly define the data that is loaded into the cache but it is possible to anticipate the prefetching strategy employed by the processor or compiler. With the prefetching strategy available, it is possible to define data types to cause the processor to load the most useful data into the cache. For example, in one example, the program code causes the processor to instantiate an array containing the fields that are geographically close or visible. The compiler and processor will assume that values in an array are most likely to be used in short succession. Therefore, defining the array causes the processor to store the array in the processor cache. The processor can then iterate over the array very efficiently. Again, the array elements are the nodes and edges of the visibility graph read from persistent storage using memory mapping.

Finally, it is noted that the marching squares algorithm can be parallelized since the calculation of densities and the processing of 2×2 squares are independent of each other. In one example, the processor is programmed to create multiple threads to determine the cell densities/apply the thresholds and then assign the cells to waterways. The advantage of having multiple threads over having multiple processes or even running the steps on multiple machines is that the threads share a common memory space. As a result, the multiple threads each access a single copy of the input shoreline model from shared memory. More particularly, the multiple threads may even access the shapefile from the processor cache. This can be made possible by generating threads that process cells and squares that are geographically closely located to each other because then it is likely that the shapefile data is loaded in a single array, which, in turn, means the entire array is likely pre-fetched into the processor cache. Again, this results in a significant speedup and reduction in memory usage because the data does not need to be loaded into memory for each computation separately.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A method for generating an output shoreline model, the method comprising:
receiving historical vessel location data comprising for each of multiple vessels, multiple historical locations of that vessel;
receiving an input shoreline model defining waterways and landmasses;
determining landmass areas in the input shoreline model that include the multiple historical locations of multiple vessels from the historical vessel location data;
assigning the landmass areas in the input shoreline model that include the multiple historical locations to the waterways in the input shoreline model to thereby create an output shoreline model.

2. The method of claim 1, wherein the method further comprises:
providing a grid of cells over at least parts of the input shoreline model;
determining a density of the multiple historical locations in each cell of the grid; and
assigning the landmass to the waterway in response to the density being above a threshold.

3. The method of claim 2, wherein the method further comprises creating a polygon using the cells as points of the polygon to assign the landmass one side of the polygon to the waterway.

4. The method of claim 3, wherein creating a polygon comprises determining for each group of cells a shape of the polygon based on which cells of that group are above the threshold.

5. The method of claim 1, wherein the method further comprises performing a marching squares algorithm to assign the landmass areas to the waterways.

6. The method of claim 1, wherein the input shoreline model comprises one or more rivers represented as lines and the output shoreline model comprises the one or more rivers represented as polygon lines representing a waterway area.

7. The method of claim 1, wherein the input shoreline model and the output shoreline model are global models.

8. The method of claim 1, wherein the input shoreline model and the output shoreline model each comprise a visibility graph.

9. The method of claim 1, wherein the method further comprises interpolating a vessel path within the waterways in the output shoreline model.

10. The method of claim 1, wherein creating the output shoreline model comprises modifying the input shoreline model by subtracting areas including the multiple historical locations from the landmass areas in the input shoreline model.

11. The method of claim 1, wherein receiving the input shoreline model comprises reading a serialised file storing the input shoreline model.

12. The method of claim 11, wherein the input shoreline model comprises an adjacency matrix representing visibility between nodes of a visibility graph, and the adjacency matrix is serialised to the serialised file.

13. The method of claim 11, wherein the serialised file comprises fixed length fields.

14. The method of claim 13, wherein the method comprises using memory mapping to access the fixed length field.

15. The method of claim 12, wherein the method further comprises using a processor cache to cache fields of the serialised file that are geographically close on the processor cache.

16. The method of claim 15, wherein the method further comprises instantiating an array containing the fields that are geographically close to store the array in the processor cache and then iterating over the array.

17. The method claim 1, wherein the method further comprises performing the steps of determining and assigning in multiple threads that each access a single copy of the input shoreline model from shared memory.

18. A non-transitory computer readable medium with software code stored thereon that, when executed by a computer, causes the computer to perform the method of claim 1.

19. A computer system comprising one or more processors configured to perform the method of claim 1.
